(19) United States
(12) Patent Application Publication
(10) Pub. No.: US 2015/0111478 A1
(43) Pub. Date: Apr. 23, 2015

(54) POLISHING SYSTEM WITH LOCAL AREA RATE CONTROL

(71) Applicant: Applied Materials, Inc., Santa Clara, CA (US)

(72) Inventors: Chih Hung CHEN, Sunnyvale, CA (US); Paul D. BUTTERFIELD, San Jose, CA (US); Shou-Sung CHANG, Redwood City, CA (US)

(21) Appl. No.: 14/502,731

(22) Filed: Sep. 30, 2014

Related U.S. Application Data
(60) Provisional application No. 61/894,499, filed on Oct. 23, 2013.

(51) Int. Cl. B24B 37/10; B24B 7/22; H01L 21/306; B24B 53/017

(52) U.S. Cl. CPC B24B 37/10; B24B 53/017; B24B 7/228; H01L 21/30625
USPC 451/72; 451/280

(57) ABSTRACT

A polishing module including a chuck having a substrate receiving surface and a perimeter, and one or more polishing pads positioned about the perimeter of the chuck, wherein each of the one or more polishing pads are movable in a sweep pattern adjacent the substrate receiving surface of the chuck and are limited in radial movement to about less than one-half of the radius of the chuck measured from the perimeter of the chuck.

### CROSS-REFERENCE TO RELATED APPLICATIONS

This application claims benefit of U.S. Provisional Patent Application Ser. No. 61/894,499 (Atty Docket No. 021009USAL) filed Oct. 23, 2013, which application is hereby incorporated by reference herein.

### BACKGROUND

1. Field

Embodiments of the present disclosure generally relate to methods and apparatus for polishing a substrate, such as a semiconductor wafer. More particularly, to methods and apparatus for polishing an edge of a substrate in an electronic device fabrication process.

2. Description of the Related Art

Chemical mechanical polishing is one process commonly used in the manufacture of high-density integrated circuits to planarize or polish a layer of material deposited on a substrate by moving a feature side, i.e., a deposit receiving surface, of the substrate in contact with a polishing pad while in the presence of a polishing fluid. In a typical polishing process, the substrate is retained in a carrier head that urges or presses the backside of the substrate toward a polishing pad. Material is removed from the feature side of the substrate that is in contact with the polishing pad through a combination of chemical and mechanical activity.

The carrier head may contain multiple individually controlled pressure regions that apply differential pressure to different regions of the substrate. For example, if greater material removal is desired at peripheral edges of the substrate as compared to the material removal desired at the center of the substrate, the carrier head may be used to apply more pressure to the peripheral edges of the substrate. However, the stiffness of the substrate tends to redistribute the pressure applied to the substrate by the carrier head such that the pressure applied to the substrate may be spread or smoothed. The smoothing effect makes local pressure application, for local material removal, difficult if not impossible.

Therefore, there is a need for a method and apparatus that facilitates removal of materials from local areas of the substrate.

### SUMMARY

Embodiments of the present disclosure generally relate to methods and apparatus for polishing a substrate, such as a semiconductor wafer. In one embodiment, a polishing module is provided. The module includes a chuck having a substrate receiving surface and a perimeter, and one or more polishing pads positioned about the perimeter of the chuck, wherein each of the one or more polishing pads are movable in a sweep pattern adjacent the substrate receiving surface of the chuck and are limited in radial movement to about less than one-half of the radius of the chuck measured from the perimeter of the chuck.

In another embodiment, a polishing module is provided. The module includes a chuck having a perimeter region disposed in a first plane and a substrate receiving surface disposed radially inward of the perimeter region in a second plane, and one or more polishing pads movably supported about the perimeter region of the chuck, wherein each of the one or more polishing pads are movable in a sweep pattern adjacent the substrate receiving surface of the chuck and are limited in radial movement to about less than one-half of a radius of the chuck measured from a circumference of the substrate receiving surface.

In another embodiment, a polishing module is provided. The module includes a chuck having a perimeter region disposed in a first plane and a substrate receiving surface disposed radially inward of the perimeter region in a second plane, wherein the first plane is different than the second plane, one or more polishing pads positioned about the perimeter of the chuck in the first plane, and a conditioning ring disposed on the perimeter region of the chuck in the second plane, wherein each of the one or more polishing pads are movable in a sweep pattern adjacent the substrate receiving surface of the chuck and are limited in radial movement to about less than one-half of the radius of the chuck as measured from the perimeter of the chuck.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a partial sectional view of one embodiment of a processing station.

FIG. 1B is a schematic sectional view of one embodiment of a polishing module.

FIG. 2A is a side cross-sectional view of another embodiment of a polishing module.

FIG. 2B is an isometric top view of the polishing module shown in FIG. 2A.

FIG. 3A is a side cross-sectional view of another embodiment of a polishing module.

FIG. 3B is an isometric top view of a polishing pad flexure device shown in FIG. 3A.

FIG. 4A is an isometric view of one embodiment of the flex ring device of FIG. 3A.

FIGS. 4B through 4D show various modes of movement of the flex ring device of FIG. 4A.

FIG. 5A is a side cross-sectional view of another embodiment of a polishing module.

FIG. 5B is an enlarged isometric side cross-sectional view of the flexure device of FIG. 5A.

FIGS. 6A-6C are bottom plan views of various embodiments of the polishing pads that may be coupled to the support arms of the polishing modules as described herein.

FIG. 6D is a side cross-sectional view of the polishing pad shown in FIG. 6C.

FIG. 7A is a side cross-sectional view of one embodiment of a polishing pad.

FIG. 7B is a side cross-sectional view of another embodiment of a polishing pad.

FIG. 8 is a partial side cross-sectional view of another embodiment of a polishing module.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the disclosure provide a polishing system and a polishing module utilized to polish a peripheral edge of a substrate in conjunction with a polishing system. Embodiments of the polishing module as described herein provide fine resolution (e.g., less than about 3 millimeters (mm)) in the radial direction and theta (Θ) direction rate control. Aspects of the disclosure include improved local polishing control with limited dishing and/or erosion in the local areas.

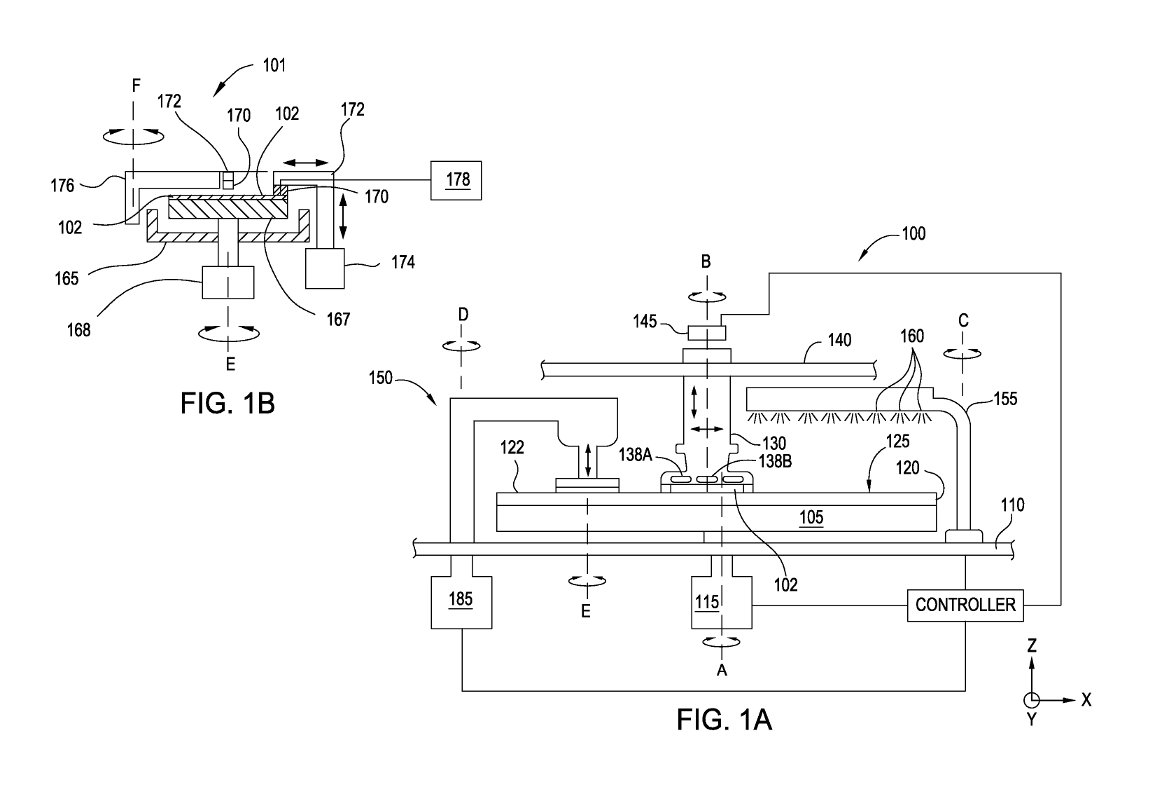

FIG. 1A is a partial sectional view of one embodiment of a processing station 100 that is configured to perform a polishing process, such as a chemical mechanical polishing (CMP) process or an electrochemical mechanical polishing (ECMP) process. FIG. 1B is a schematic sectional view of one embodiment of a polishing module 101 that, when used in conjunction with the processing station 100, comprises one embodiment of a polishing system. The processing station 100 may be used to perform a global CMP process to polish a major side of a substrate 102. In the event that a peripheral edge of the substrate 102 is not polished sufficiently using the processing station 100, the polishing module 101 may be used to polish the peripheral edge. The polishing module 101 may be used to polish the edge before or after a global CMP process performed by the processing station 100. Each of the processing station 100 and the polishing module 101 may be a stand-alone unit or part of a larger processing system. Examples of a larger processing system that may be adapted to utilize one or both of the processing station 100 and the polishing module 101 include REFLEXION®, REFLEXION® LK, REFLEXION® GT™, MIRRA MESA® polishing systems available from Applied Materials, Inc., located in Santa Clara, Calif., among other polishing systems, as well as polishing systems from other manufacturers.

The processing station 100 includes a platen 105 rotatably supported on a base 110. The platen 105 is operably coupled to a drive motor 115 adapted to rotate the platen 105 about a rotational axis A. The platen 105 supports a polishing pad 120 made of a polishing material 122. In one embodiment, the polishing material 122 of the polishing pad 120 is a commercially available pad material, such as polymer based pad materials typically utilized in CMP processes. The polymer material may be a polyurethane, a polycarbonate, fluoropolymers, polytetrafluoroethylene (PTFE), polyphenylene sulfide (PPS), or combinations thereof. The polishing material 122 may further comprise open or closed cell foamed polymers, elastomers, felt, impregnated felt, plastics, and like materials compatible with the processing chemistries. In another embodiment, the polishing material 122 is a felt material impregnated with a porous coating. In other embodiments, the polishing material 122 includes a material that is at least partially conductive.

A carrier head 130 is disposed above a processing surface 125 of the polishing pad 120. The carrier head 130 retains the substrate 102 and controllably urges the substrate 102 towards the processing surface 125 (along the Z axis) of the polishing pad 120 during processing. The carrier head 130 contains a zoned pressure control device shown as an outer zone pressure applicator 138A and an inner zone pressure applicator 138B (both shown in phantom). The outer zone pressure applicator 138A and the inner zone pressure applicator 138B apply a variable pressure to the backside of the substrate 102 during polishing. The outer zone pressure applicator 138A and the inner zone pressure applicator 138B may be adjusted to provide more pressure against the edge region of the substrate 102 as compared to the center area of the substrate 102, and vice versa. Thus, the outer zone pressure applicator 138A and the inner zone pressure applicator 138B are used to tune the polishing process.

The carrier head 130 is mounted to a support member 140 that supports the carrier head 130 and facilitates movement of the carrier head 130 relative to the polishing pad 120. The support member 140 may be coupled to the base 110 or mounted above the processing station 100 in a manner that suspends the carrier head 130 above the polishing pad 120. In one embodiment, the support member 140 is a linear or a circular track that is mounted above the processing station 100. The carrier head 130 is coupled to a drive system 145 that provides at least rotational movement of the carrier head 130 about a rotational axis B. The drive system 145 may additionally be configured to move the carrier head 130 along the support member 140 laterally (X and/or Y axes) relative to the polishing pad 120. In one embodiment, the drive system 145 moves the carrier head 130 vertically (Z axis) relative to the polishing pad 120 in addition to lateral movement. For example, the drive system 145 may be utilized to move the substrate 102 towards the polishing pad 120 in addition to providing rotational and/or lateral movement of the substrate 102 relative to the polishing pad 120. The lateral movement of the carrier head 130 may be a linear or an arcing or sweeping motion.

A conditioning device 150 and a fluid applicator 155 are shown positioned over the processing surface 125 of the polishing pad 120. The conditioning device 150 is coupled to the base 110 and includes an actuator 185 that may be adapted to rotate the conditioning device 150 or move the conditioning device 150 in one or more linear directions relative to the polishing pad 120 and/or the base 110. The fluid applicator 155 includes one or more nozzles 160 adapted to deliver polishing fluids to a portion of the polishing pad 120. The fluid applicator 155 is rotatably coupled to the base 110. In one embodiment, the fluid applicator 155 is adapted to rotate about a rotational axis C and provides a polishing fluid that is directed toward the processing surface 125. The polishing fluid may be a chemical solution, water, a polishing compound, a cleaning solution, or a combination thereof.

FIG. 1B is a schematic sectional view of one embodiment of the polishing module 101. The polishing module 101 includes a base 165 supporting a chuck 167, which rotatably supports the substrate 102 thereon. The chuck 167 may be a vacuum chuck in one embodiment. The chuck 167 is coupled to a drive device 168, which may be a motor or actuator, providing at least rotational movement of the chuck 167 about axis E. The substrate 102 is disposed on the chuck 167 in a “face-up” orientation such that the feature side of the substrate 102 faces one or more polishing pads 170. Each of the one or more polishing pads 170 are utilized to polish the peripheral edge of the substrate 102 before or after polishing of the substrate 102 in the processing station 100 of FIG. 1A. The one or more polishing pads 170 comprise a commercially available pad material, such as polymer based pad materials typically utilized in CMP processes. Each of the one or more polishing pads 170 are coupled to a support arm 172 that moves the pads relative to the substrate 102. Each of the support arms 172 may be coupled to an actuator 174 that moves the support arm 172 (and the polishing pad 170 mounted thereon) vertically (Z direction) as well as laterally (X and/or Y direction) relative to the substrate 102 mounted on the chuck 167. The actuators 174 may also be utilized to move the support arm 172 (and the polishing pad 170 mounted thereon) in an orbital or circular motion relative to the substrate 102.

The one or more polishing pads 170 may comprise a single pad shaped as a ring-shaped polishing pad made of a polishing material that includes a diameter that is sized to substantially match the diameter of the substrate 102. For example, if the diameter of the substrate 102 is 300 mm, then the ring-shaped polishing pad may include an inside diameter of about 290 mm to about 295 mm, and an outside diameter of about 300 mm to about 310 mm. In the embodiment shown in FIG. 1B, the one or more polishing pads 170 may include discrete arc segments having diameters as described above. In other embodiments, the one or more polishing pads 170 may include arc-shaped segments such as a crescent shape and/or multiple discrete shapes of pad material disposed on each support arm 172. In one embodiment, a polishing fluid from a source 178 may be applied through the polishing pad 170.

The polishing module 101 also includes a fluid applicator 176 to provide a polishing fluid to the surface of the substrate 102. The fluid applicator 176 may include nozzles (not shown) and be configured similar to the fluid applicator 155 described in FIG. 1A. The fluid applicator 176 is adapted to rotate about axis F and may provide the same polishing fluids as the fluid applicator 155. The base 165 may be utilized as a basin to collect polishing fluid from the fluid applicator 176.

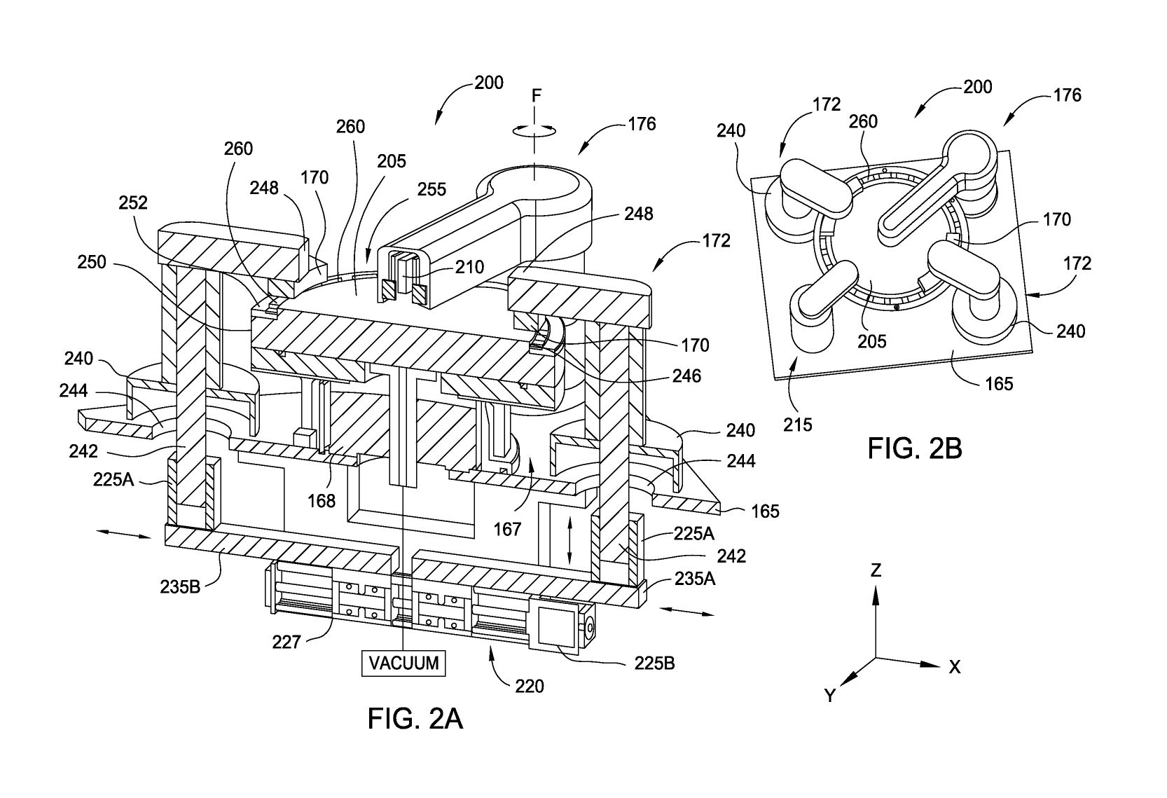

FIG. 2A is a side cross-sectional view of another embodiment of a polishing module 200 that may be used alone or in conjunction with the processing station 100 of FIG. 1A. FIG. 2B is an isometric top view of the polishing module 200 shown in FIG. 2A. The polishing module 200 includes the chuck 167 which in this embodiment is coupled to a vacuum source. The chuck 167 includes a substrate receiving surface 205 that includes a plurality of openings (not shown) that are in communication with the vacuum source such that a substrate (shown in FIG. 1B) disposed on the substrate receiving surface 205 may be secured thereon. The chuck 167 also includes the drive device 168 that rotates the chuck 167. The fluid applicator 176 is also shown, which includes a nozzle 210 for delivering polishing fluids to the chuck 167. A metrology device 215 (shown in FIG. 2B) may also be coupled to the base 165. The metrology device 215 may be utilized to provide an in-situ metric of polishing progress by measuring a metal or dielectric film thickness on the substrate (not shown) during polishing. The metrology device 215 may be an eddy current sensor, an optical sensor, or other sensing device that may be used to determine metal or dielectric film thickness. Other methods for ex-situ metrology feedback include pre-determining parameters such as location of thick/thin areas of deposition on the wafer, the motion recipe for the chuck 167 and/or the polishing pads 170, polishing time, as well as the downforce to be used. Ex-situ feedback can also be used to determine the final profile of the polished film. In situ metrology can be used to optimize polishing by monitoring progress of the parameters determined by the ex-situ metrology.

Each of the support arms 172 are movably mounted on the base 165 by an actuator assembly 220. The actuator assembly 220 includes a first actuator 225A and a second actuator 225B. The first actuator 225A may be used to move each support arm 172 vertically (Z direction) and the second actuator 225B may be used to move each support arm 172 laterally (X direction, Y direction, or combinations thereof). The first actuator 225A may also be used to provide a controllable downforce that urges the polishing pads 170 towards the substrate (not shown). While only 2 support arms 172 having polishing pads 170 thereon are shown in FIGS. 2A and 2B, the polishing module 200 is not limited to two support arms 172. The polishing module 200 may include any number of support arms 172 as allowed by the circumference of the chuck 167 and sufficient space allowance for the fluid applicator 176 and the metrology device 215, as well as space for sweeping movement of the support arms 172 (and polishing pads 170 mounted thereon).

The actuator assembly 220 may comprise a linear movement mechanism 227, which may be a slide mechanism or ball screw coupled to the second actuator 225B. Likewise, each of the first actuators 225A may comprise a linear slide mechanism, a ball screw, or a cylinder slide mechanism that moves the support arm 172 vertically. The actuator assembly 220 also includes support arms 235A, 235B coupled between the first actuator 225A and the linear movement mechanism 227. Each of the support arms 235A, 235B may be actuated simultaneously or individually by the second actuator 225B. Thus, lateral movement of the support arms 172 (and polishing pads 170 mounted thereon) may sweep radially on the substrate (not shown) in a synchronized or non-synchronized manner. A dynamic seal 240 may be disposed about a support shaft 242 that may be part of the first actuator 225A. The dynamic seal 240 may be a labyrinth seal that is coupled between the support shaft 242 and the base 165.

The support shaft 242 is disposed in an opening 244 formed in the base 165 that allows lateral movement of the support arms 172 based on the movement provided by the actuator assembly 220. The opening 244 is sized to allow sufficient lateral movement of the support shaft 242 such that the support arms 172 (and polishing pads 170 mounted thereon) may move from a perimeter 246 of the substrate receiving surface 205 toward the center thereof to about one half the radius of the substrate receiving surface 205. In one embodiment, the substrate receiving surface 205 has a diameter that is substantially the same as the diameter of a substrate that would be mounted thereon during processing. For example, if the radius of the substrate receiving surface 205 is 150 mm, the support arms 172, particularly the polishing pads 170 mounted thereon, may move radially from about 150 mm (e.g., the perimeter 246) to about 75 mm inward toward the center, and back to the perimeter 246. The term “about” may be defined as 0.00 mm (zero mm) to no more than 5 mm past one half of the radius of the substrate receiving surface 205 which is about 75 mm in the example above.

Additionally, the opening 244 is sized to allow sufficient lateral movement of the support shaft 242 such that an end 248 of the support arms 172 may be moved past a perimeter 250 of the chuck 167. Thus, when the fluid applicator 176 is rotated about axis F, and the end 248 of the support arms 172 are moved outward to clear the perimeter 250, the a substrate may be transferred onto or off of the substrate receiving surface 205. The substrate may be transferred by a robot arm or end effector to or from the processing station 100 shown in FIG. 1A before or after a global CMP process. In one embodiment, the substrate may be transferred to or from the processing station 100 using the carrier head 130 (shown in FIG. 1A).

The chuck 167 may additionally include a peripheral edge region 252 positioned radially outward from the substrate receiving surface 205. The peripheral edge region 252 may be at a plane that is offset from (i.e., recessed below) a plane of the substrate receiving surface 205. The peripheral edge region 252 may also include a conditioning ring 255 that is used to condition the polishing pads 170. The height of the conditioning ring 255 may also be at a plane that is offset from (i.e., recessed below) a plane of the substrate receiving surface 205. The conditioning ring 255 may be one or more discrete abrasive elements 260 that comprise rectangular and/or arced members made of, or including, abrasive particles or materials. In one embodiment, the conditioning ring 255 includes a plurality of discrete abrasive elements 260, each of which are shaped as an arc segment. Each of the discrete abrasive elements 260 may comprise diamond particles that are used to condition the polishing pads 170 in between polishing processes. For example, before or after a substrate is placed on the substrate receiving surface 205 of the chuck 167, the support arms 172 may be moved adjacent the conditioning ring 255 and actuated toward the conditioning ring 255 to cause the polishing pads 170 to contact the discrete abrasive elements 260. The chuck 167 may be rotated during this contact to condition the polishing pads 170. In one embodiment, the time period for conditioning of all of the polishing pads 170 is less than about 2 seconds, which may increase throughput of the polishing module 200. In one embodiment, conditioning of the polishing pads 170 may be performed during transfer of a substrate to or from the substrate receiving surface 205 of the chuck 167.

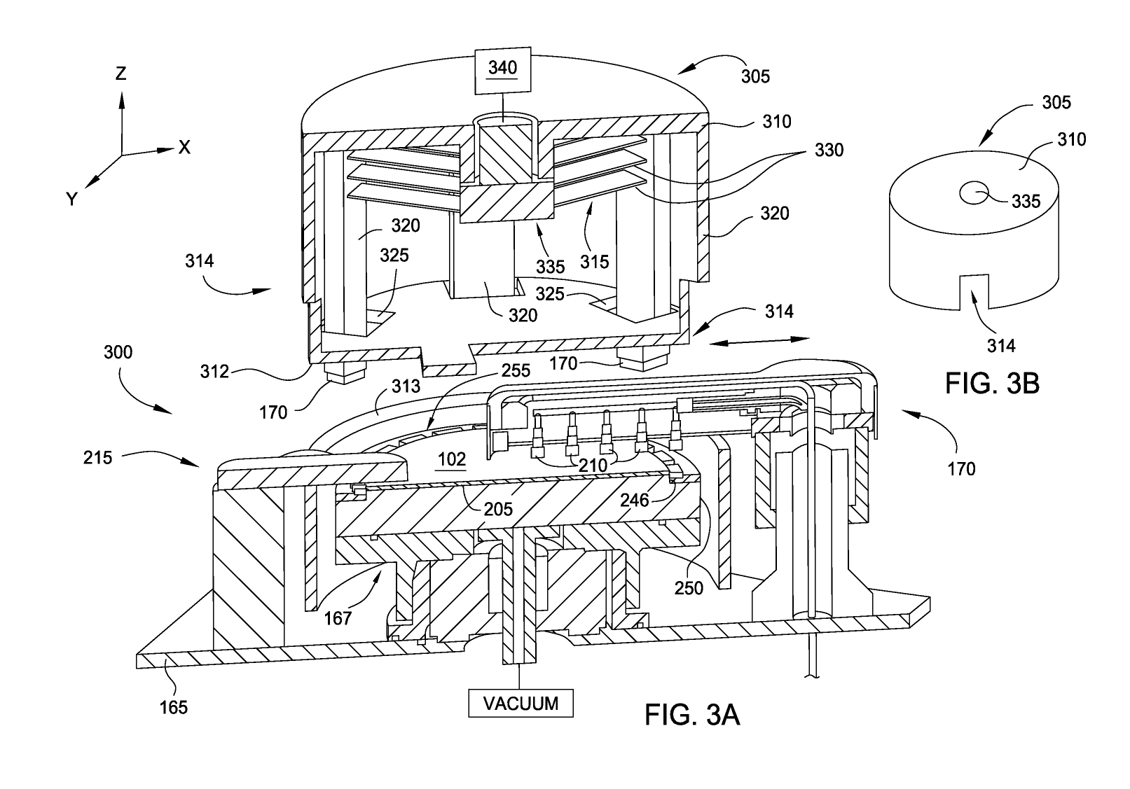

FIG. 3A is a side cross-sectional view of another embodiment of a polishing module 300 that may be used alone or in conjunction with the processing station 100 of FIG. 1A. The polishing module 300 is substantially similar to the embodiment of the polishing module 200 shown in FIGS. 2A and 2B with the following exceptions. In this embodiment, the polishing module 300 includes a polishing pad flexure device 305 that may be utilized to replace multiple support arms 172 as described in FIGS. 2A and 2B. Reducing the number of support arms 172 by utilizing the polishing pad flexure device 305 may decrease costs of the polishing module 300 as the number of actuators driving the support arms 172 will be reduced. FIG. 3B is an isometric top view of the polishing pad flexure device 305 shown in FIG. 3A.

The polishing pad flexure device 305 includes a housing 310 that contains a flex ring device 315. The flex ring device 315 includes a plurality of polishing members 320 that are movably disposed within openings 325 formed in the housing 310. The housing 310 is configured to cover the polishing module 300 on an upper side thereof. Cut-outs 314 are formed in the housing 310 to accommodate the fluid applicator 176 and the metrology device 215. Each of the polishing members 320 are coupled to one or more flexure members 330 that are coupled to a central hub 335. The central hub 335 may be coupled to an actuator 340. The actuator 340 may be used to control movement of the central hub 335 and, ultimately, the movement of the polishing members 320. Each of the openings 325 are sized to allow lateral movement of the polishing members 320 therein in a sweep pattern when a substrate 102 is being polished. Additionally, each of the openings 325 are sized to allow movement of the polishing members 320 to a position to be in contact with the conditioning ring 255. The actuator 340 may also be utilized to provide a controllable downforce to each of the polishing members 320.

Each of the polishing members 320 may include a polishing pad 170 located thereon. Alternatively, the polishing members 320 may be made of a polishing pad material. Each of the polishing members 320 are configured to move relative to the housing 310 during polishing and/or conditioning. In one embodiment, the housing 310 is adapted to essentially “float” in the vertical direction (Z direction) above the substrate receiving surface 205. In this embodiment, the housing 310 may be secured laterally thereby aligning the polishing members 320 about the edge of a substrate 102 positioned on the substrate receiving surface 205. The actuator 340 may be used to drive the polishing members 320 downward (Z-direction) toward the surface of the substrate 102. The actuator 340 may also move the polishing members 320 radially by driving the central hub 335 in order to change the positions of the flexure members 330. In one aspect, the weight of the polishing pad flexure device 305 provides a portion of the downforce while the polishing members 320 are moved on the substrate 102. Additionally or alternatively, another actuator (not shown) may be coupled to the housing 310 to provide a controllable downforce to the housing 310. In another embodiment, the housing 310 may include a lower surface 312 that is at least partially supported by a support ring 313 surrounding the chuck 167 during operation. In this embodiment, the housing 310 is secured relative to the chuck 167 thereby providing movement of the polishing members 320 provided by the actuator 340.

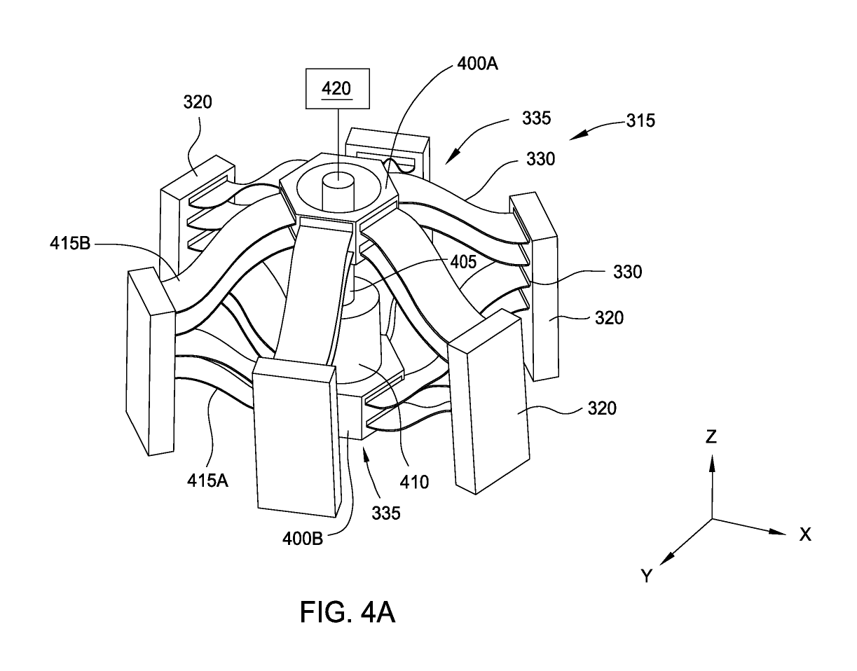

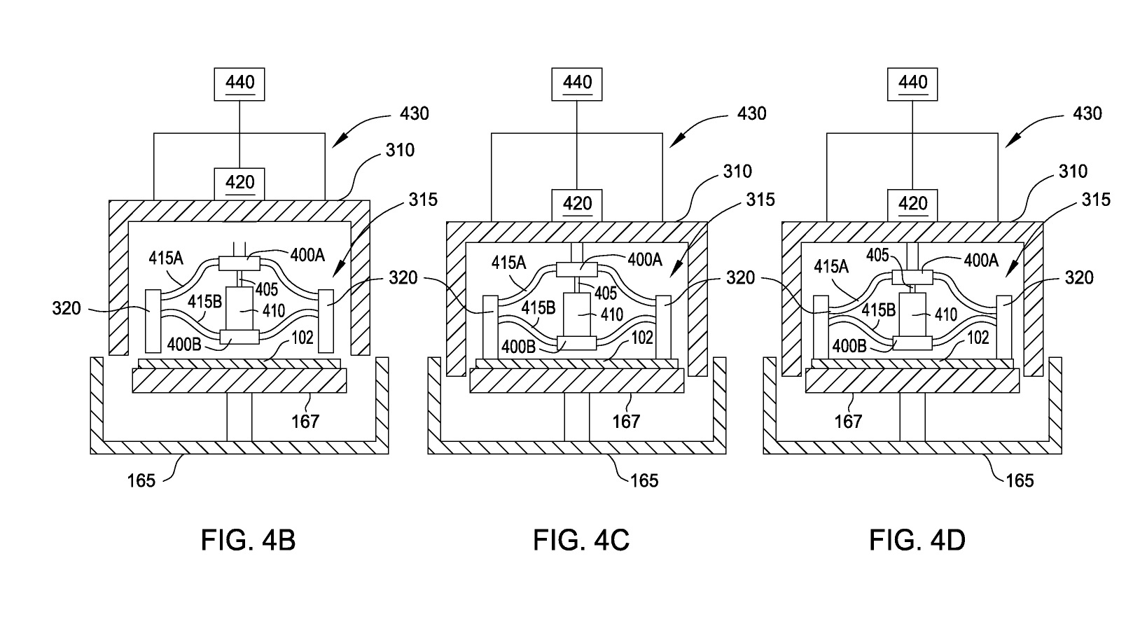

FIG. 4A is an isometric view of one embodiment of the flex ring device 315 of FIG. 3A. The flex ring device 315 includes the central hub 335 shown here as a first hub member 400A and a second hub member 400B. Each of the first hub member 400A and the second hub member 400B are coupled together by a shaft 405 of a first actuator 410. The first actuator 410 is used to move the first hub member 400A away and towards the second hub member 400B thereby changing the distance between the central hub 335 and the polishing members 320. Actuation of the first actuator 410 thus provides radial movement of the polishing members 320 during polishing. The flexure members 330, which are shown as first flexure members 415A and second flexure members 415B, provide lateral stability (X and/or Y direction) of the flexure members 330. Therefore, when the substrate (shown in FIG. 3A) is rotated, the polishing members 320 will have a longitudinal axis that remains substantially orthogonal to the substrate. A second actuator 420 may be coupled to the flex ring device 315 to provide a controllable downforce to the polishing members 320.

FIGS. 4B through 4D show various modes of movement of the flex ring device 315 of FIG. 4A. In FIGS. 4B through 4D, the housing 310 is coupled to a support member 430 that stabilizes the housing 310 relative to the chuck 167 and the base 165. A motor 440 may also be coupled to the support member 430 that may lift or lower the housing 310 relative to the chuck 167 and the base 165. The motor 440 may also provide a downforce to the housing 310 that is transmitted to each of the polishing members 320 during a polishing or conditioning process.

FIG. 4B shows the flex ring device 315 in a position either before or after polishing a substrate 102. In this position the polishing members 320 are spaced apart from the surface of the substrate 102. The spaced apart relationship may be caused by one or a combination of movement provided by the first actuator 410 (i.e., moving the first hub member 400A and the second hub member 400B to be spaced apart) and the second actuator 420 (i.e., moving the first hub member 400A and the second hub member 400B at the same time).

FIG. 4C shows the polishing members 320 of the flex ring device 315 in contact with the surface of the substrate 102. The position of the polishing members 320 may be a first position in a sweep pattern on the substrate 102. For example, in the first position, the polishing members 320 may be in an inwardly radial sweep across the edge of the substrate 102. FIG. 4D shows the polishing members 320 of the flex ring device 315 in contact with the surface of the substrate 102 at a second position near the edge of the substrate 102. The movement between the first position and the second position may be caused by movement of the first hub member 400A and the second hub member 400B by the first actuator 410. The first position and the second position may correspond to a change in a diameter defined by the polishing members 320 about the central hub 335 (i.e., distance between an outer surface of two opposing polishing members 320). In one example, movement of the first hub member 400A away from the second hub member 400B (or vice versa) causes the diameter of the polishing members 320 makes the diameter decrease. Likewise, movement of the first hub member 400A toward the second hub member 400B (or vice versa) causes the diameter of the polishing members 320 makes the diameter increase. The radial displacement may be about 42 mm in one embodiment. Thus, constant movement of the first hub member 400A toward and away from the second hub member 400B (or vice versa) provides a radial sweep pattern across the edge of the substrate 102.

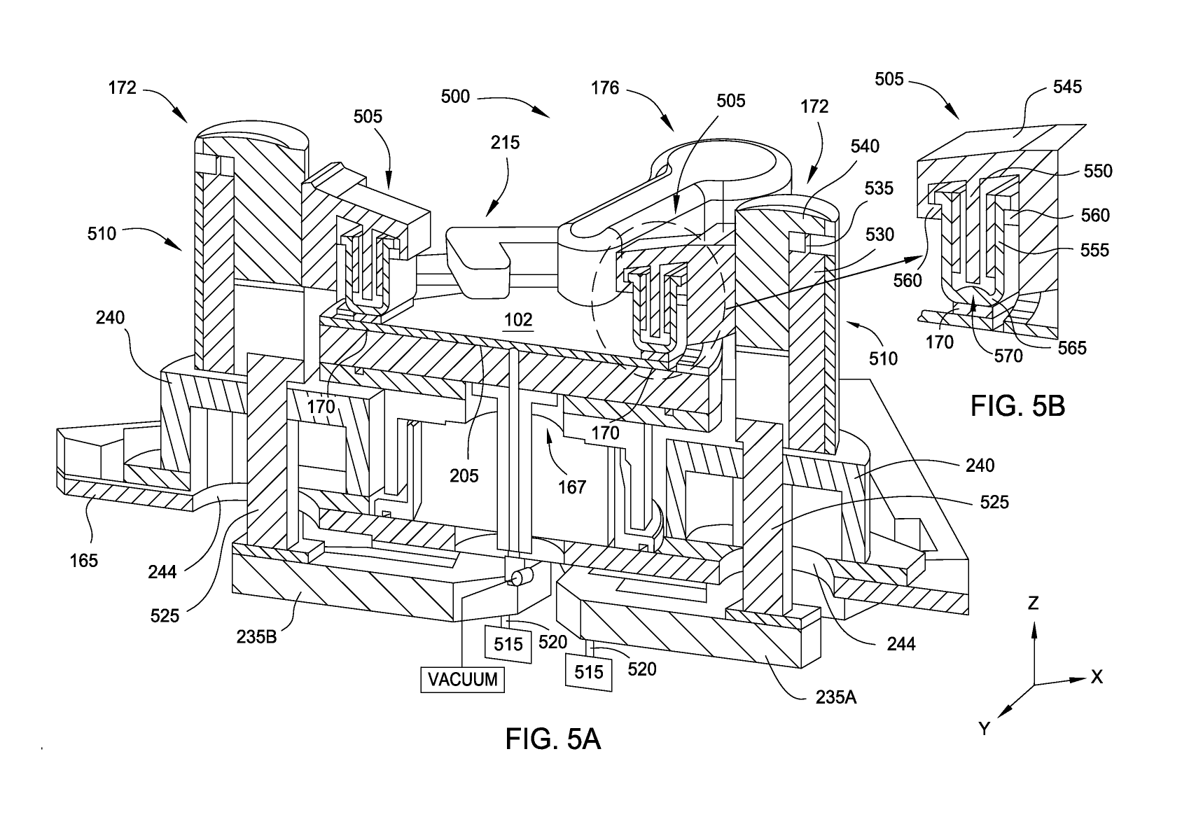

FIG. 5A is a side cross-sectional view of another embodiment of a polishing module 500 that may be used alone or in conjunction with the processing station 100 of FIG. 1A. The polishing module 500 is substantially similar to the embodiment of the polishing module 200 shown in FIGS. 2A and 2B with the following exceptions. In this embodiment, the polishing module 500 includes a flexure device 505 coupled to the support arms 172. In addition, the support arms 172 include a vertical actuating device 510 located on the outside of the dynamic seal 240 (as opposed to below the dynamic seal 240 as shown in FIG. 2A). Additionally, the actuator assembly 220 includes actuator devices 515 coupled to each of the support arms 235A, 235B.

The actuator devices 515 are coupled to an eccentric shaft 520 that provides orbital movement of the support arms 172 (and polishing pads 170 coupled thereto). In this embodiment, the openings 244 are sized to allow orbital (i.e., circular or oval) movement of a shaft 525 that is coupled between each of the support arms 235A, 235B and the support arms 172 having the polishing pads 170 mounted thereon.

The vertical actuating device 510 of the support arms 172 includes an actuator 530 that moves a shaft 535 and a support member 540 vertically (Z direction). The flexure device 505 is coupled to the support member 540 and moves relative to the substrate 102 and/or the chuck 167 when the actuator 530 is energized. The polishing pad 170 is coupled to a lower surface of the flexure device 505, which is more clearly shown in FIG. 5B. The combination of the vertical actuating device 510 and the eccentric shaft 520 coupled to the support arms 235A, 235B provides vertical (Z direction) as well as movement in the horizontal plane (X and Y directions) to provide an orbital sweep pattern on the substrate 102. Downforce may be controlled by the vertical actuating device 510.

FIG. 5B is an enlarged isometric side cross-sectional view of the flexure device 505 of FIG. 5A. The flexure device 505 includes a rigid body 545 that may include a spine 550 extending from one side of the rigid body 545. The flexure device 505 also includes a flexible member 555 that is supported by ends 560 of the rigid body 545. The flexible member 555 may be U-shaped and is suspended within the rigid body 545 by the ends 560 of the rigid body 545. The polishing pad 170 is coupled to a lower portion 565 of the flexible member 555. The flexible member 555 is configured to allow some movement of the polishing pad 170 during polishing and/or conditioning. In one aspect, the flexible member 555 compensates for misalignment resulting from manufacturing imperfections in the chuck 167. The lower portion 565 may include a hump 570 (a region of increased thickness) to tune the flexibility of the flexible member 555.

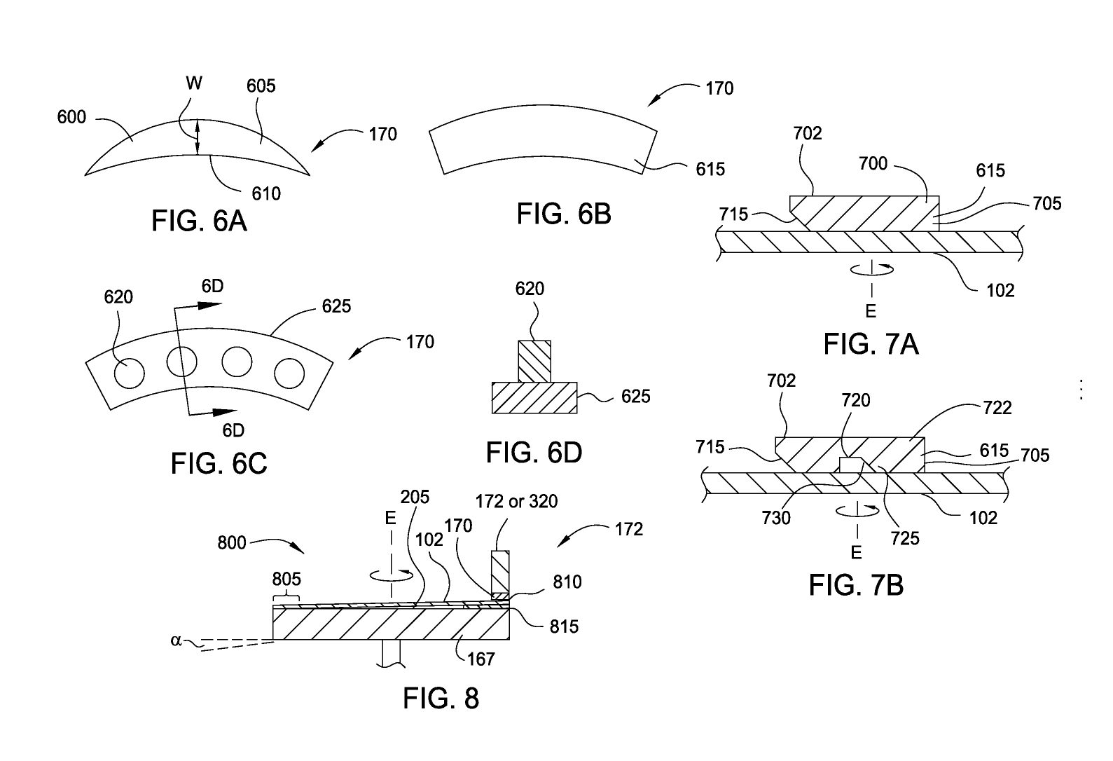

FIGS. 6A-6C are bottom plan views of various embodiments of the polishing pads that may be coupled to the support arms 172 of the polishing modules 101, 200, 300 and 500 as described herein. FIG. 6A shows a polishing pad 170 having a body 600 that is crescent shaped. The body 600 may include a width W that is about 10 mm or less, to about 1 mm. The length of the body 600 may be determined by the width W. Additionally, the body 600 may include an outer radius 605 that substantially equals the radius of the substrate receiving surface 205 (shown in FIG. 2A) or the substrate 102 (shown in FIG. 3A or 5A) mounted thereon. In one example, the outer radius may be about 150 mm for a substrate receiving surface 205 having a radius of about 150 mm. An inside radius 610 may be the same as the outer radius 605, less than the outer radius 605, or greater than the outer radius 605.

FIG. 6B shows a polishing pad 170 having a body 615 that is shaped as an arc segment. The body 615 may have a width similar to the embodiment shown in FIG. 6A. Additionally, the body 615 may include inside and outside radii that are substantially similar to the embodiment shown in FIG. 6A.

FIG. 6C shows a polishing pad 170 having a plurality of protruded structures 620 formed on, or bonded to, a support substrate 625. FIG. 6D is a side cross-sectional view of the polishing pad 170 shown in FIG. 6C. Each of the plurality of protruded structures 620 may be columnar structures having a circular shape in plan view as shown, or a rectangular, or other polygonal shape, in plan view. Each of the protruded structures 620 may be made of a polishing material as described herein.

FIG. 7A is a side cross-sectional view of one embodiment of a polishing pad 700 disposed on a substrate 102. The polishing pad 700 may be the polishing pad 170 shown and described in FIGS. 6A and 6B. In this embodiment, the polishing pad 700 is contacting the substrate 102 that may be rotating about axis E (which would be during a polishing process on any of the polishing modules 101, 200, 300 and 500 as described herein). While the axis E is shown as counterclockwise, the axis E may also be clockwise. During polishing, the body 615 of the polishing pad 700 includes a leading edge 702 and a trailing edge 705. Frictional forces between the rotating substrate and the contact surface of the polishing pad 700 may cause the leading edge 702 to plastically or elastically deform, such as by bending or folding of the body 615 upon itself. In one example, the leading edge 702 may bend upon itself toward the trailing edge 705, which results in undesirable polishing results as well as damage to the polishing pad 700. To counter the possibility of deformation, the leading edge 702 includes a recessed portion 715. The recessed portion 715 may be a bevel, a chamfer or a radius. The recessed portion 715 may include the entire leading edge 702 or a portion thereof, as shown.

FIG. 7B is a side cross-sectional view of another embodiment of a polishing pad 722. The polishing pad 722 may be substantially similar to the embodiment shown in FIG. 7A. The polishing pad 722 shown in FIG. 7B also includes a channel or groove 720 formed on a lower surface of the body 615. The groove 720 may be formed near a midsection of the body 615 and may provide enhanced transportation of polishing fluid during a polishing process. A trailing edge 725 of the groove 720 may also include a recessed portion 730 similar to the recessed portion 715 described in FIG. 7A.

FIG. 8 is a partial side cross-sectional view of another embodiment of a polishing module 800 that may be any one of the polishing modules 101, 200, 300 and 500 as described herein. A substrate 102 having a peripheral edge 805 is shown on the chuck 167. The peripheral edge 805 includes an annular band along the outer radius of the substrate 102. The substrate 102 may have a region 810 where deposition is thicker than on other portions of the peripheral edge 805. To effectively remove this region 810 relative to other portions of the peripheral edge 805, it may be desirable to apply a greater downforce to the region 810 as compared to a downforce at other portions of the peripheral edge 805 (where deposition thickness is less than the thickness at the region 810).

In one embodiment, the actuator that controls the support arm 172 (shown in FIGS. 1B, 2A, 2B and 5A) may be actuated to provide greater downforce when the region 810 is proximate the polishing pad 170, and provide a lesser downforce when the region 810 rotates away from the polishing pad 170. However, when the chuck 167 and substrate 102 are rotated at a speed that may exceed the reaction speed of the actuator that controls the support arm 172 (shown in FIGS. 1B, 2A, 2B and 5A), a shim 815 may be disposed between the substrate receiving surface 205 of the chuck 167 and a lower surface of the substrate 102. The shim 815 may be one or more pieces of a rigid or dense material that may be shaped as thin strip or a wedge. The shim 815 may be positioned between the substrate receiving surface 205 of the chuck 167 and a lower surface of the substrate 102 according to positions of one or more regions 810 in order to raise the region 810 above the plane of other portions of the peripheral edge 805. Thus, when the region 810 passes under the polishing pad 170, force between the substrate and the substrate 102 is increased in order to enhance removal of the material of the region 810. Other regions of the peripheral edge 805 will experience a suitable downforce to effect material removal, but the force may be less than the force at the region 810. The shim 815 may also be used with the polishing module 300 shown in FIG. 3A. Additionally or alternatively, the chuck 167 may be adapted to tilt such that any regions 810 on a substrate will maintain a greater height as compared to the remainder of the peripheral edge 805. In this embodiment, the shim 815 may or may not be used and the chuck 167 may be caused to tilt at an angle α thus elevating the portion of the substrate receiving surface 205 of the chuck 167 where the region 810 is located. The tilt at angle α may be maintained during rotation of the chuck 167 about axis E such that the portion of the substrate receiving surface 205 of the chuck 167 (corresponding to the region 810) is elevated at each revolution under the polishing pad 170.

While the foregoing is directed to embodiments of the present disclosure, other and further embodiments of the disclosure may be devised without departing from the basic scope thereof, and the scope thereof is determined by the claims that follow.

1. A polishing module, comprising:
a chuck having a substrate receiving surface and a perimeter; and
one or more polishing pads positioned about the perimeter of the chuck, wherein each of the one or more polishing pads are movable in a sweep pattern adjacent the substrate receiving surface of the chuck and are limited in radial movement to about less than one-half of the radius of the chuck as measured from the perimeter of the chuck.

2. The module of claim 1, wherein each of the one or more polishing pads are coupled to a respective actuator that is configured to move the polishing pad coupled thereto in the sweep pattern.

3. The module of claim 2, wherein the sweep pattern is radial.

4. The module of claim 2, wherein the sweep pattern is eccentric.

5. The module of claim 1, wherein each of the one or more polishing pads are coupled to common actuator.

6. The module of claim 5, wherein the common actuator is coupled to a flex ring having a plurality of polishing members coupled thereto, each of the polishing members including one of the one or more polishing pads.

7. The module of claim 6, wherein the flex ring is disposed in a housing.

8. The module of claim 1, further comprising:
one or more support arms, each of the support arms having one of the one or more polishing pads coupled thereto.

9. The module of claim 8, wherein each of the one or more support arms are coupled to an actuator.

10. The module of claim 8, wherein the one or more support arms are coupled to a common actuator.

11. The module of claim 1, further comprising:
a conditioning ring disposed radially outward of the perimeter of the chuck.

12. The module of claim 11, wherein the conditioning ring is disposed in a plane that is different than a plane of the substrate receiving surface of the chuck.

13. A polishing module, comprising:
a chuck having a perimeter region disposed in a first plane and a substrate receiving surface disposed radially inward of the perimeter region in a second plane; and
one or more polishing pads movably supported about the perimeter region of the chuck, wherein each of the one or more polishing pads are movable in a sweep pattern adjacent the substrate receiving surface of the chuck and are limited in radial movement to about less than one-half of a radius of the chuck measured from a circumference of the substrate receiving surface.

14. The module of claim 13, wherein the first plane is different than the second plane.

15. The module of claim 15, further comprising:
a conditioning ring disposed on the perimeter region of the chuck in the second plane.

16. The module of claim 13, wherein the sweep pattern is radial.

17. The module of claim 13, wherein the sweep pattern is eccentric.

18. A polishing module, comprising:
a chuck having a perimeter region disposed in a first plane and a substrate receiving surface disposed radially inward of the perimeter region in a second plane, wherein the first plane is different than the second plane;
one or more polishing pads positioned about the perimeter of the chuck in the first plane; and
a conditioning ring disposed on the perimeter region of the chuck in the second plane, wherein each of the one or more polishing pads are movable in a sweep pattern adjacent the substrate receiving surface of the chuck and are limited in radial movement to about less than one-half of the radius of the chuck as measured from the perimeter of the chuck.

19. The module of claim 18, wherein each of the one or more polishing pads are coupled to a respective actuator that is configured to move the polishing pad coupled thereto in the sweep pattern.

20. The module of claim 18, wherein each of the one or more polishing pads are coupled to common actuator.
